(19) United States
(12) Patent Application Publication
(10) Pub. No.: US 2013/0025671 A1
(43) Pub. Date: Jan. 31, 2013

(54) METHOD FOR MANUFACTURING LIGHT-ABSORPTION LAYER FOR SOLAR CELL, METHOD FOR MANUFACTURING THIN FILM SOLAR CELL USING THE SAME, AND THIN FILM SOLAR CELL USING THE SAME

(71) Applicants: Jung Ah LIM, Gyeonggi-do (KR); Yong-Won SONG, Seoul (KR); Jae-Min HONG, Seoul (KR); Hong Thomas HAHN, Seoul (KR); Hak-Sung KIM, Seoul (KR)

(72) Inventors: Jung Ah LIM, Gyeonggi-do (KR); Yong-Won SONG, Seoul (KR); Jae-Min HONG, Seoul (KR); Hong Thomas HAHN, Seoul (KR); Hak-Sung KIM, Seoul (KR)

(73) Assignee: KOREA INSTITUTE OF SCIENCE AND TECHNOLOGY, Seoul (KR)

(21) Appl. No.: 13/557,487

(22) Filed: Jul. 25, 2012

(30) Foreign Application Priority Data
Jul. 27, 2011 (KR) 10-2011-0074781

(51) Int. Cl. H01L 31/02; H01L 31/18

(52) U.S. Cl. 136/256; 438/95; 257/E31.026

(57) ABSTRACT

Disclosed are a method of manufacturing a light-absorption layer for a solar cell, a method manufacturing a thin film solar cell using the same, and a thin film solar cell fabricated using the same. The method of manufacturing a light-absorption layer for a solar cell includes: preparing an ink composition including at least one metal precursor including at least one chalcogen element and a solvent; applying the ink composition as a precursor phase on a substrate using a solution process; and photo-sintering the ink composition applied on the substrate as a precursor phase.

### CROSS-REFERENCE TO RELATED APPLICATION

This application claims priority to and the benefit of Korean Patent Application No. 10-2011-0074781 filed in the Korean Intellectual Property Office on Jul. 27, 2011, the entire contents of which are incorporated herein by reference.

### BACKGROUND OF THE INVENTION

(a) Field of the Invention

A method of manufacturing a light-absorption layer for a solar cell, a method manufacturing a thin film solar cell using the same, and a thin film solar cell using the same are disclosed.

(b) Description of the Related Art

Recently, a copper-indium-gallium-selenide (GIGS) alloy, a copper pyrite material that is generally known as a CIGS alloy, has drawn much attention as a semiconductor operation layer.

For example, a GIGS alloy has a conversion rate of solar light into electricity of about 19%, and the best efficiency among light absorption layer materials for a solar cell.

The GIGS alloy has been formed into a thin film through various methods. In U.S. Pat. No. 5,141,464, Chen and Stewart disclose a technology for forming a CIGS film by evaporating and electrically depositing each element at a temperature ranging from about 400 to about 500° C. under a vacuum condition and applying the GIGS film to a solar cell.

In U.S. Pat. No. 5,045,409, Eberspacher discloses a method of magnetron-sputtering copper and indium and thermally sputtering selenium under a mixed atmosphere.

However, the aforementioned conventional evaporation electric deposition and magnetron sputtering methods require a large amount of investment due to a complex gas process as well as expensive vacuum equipment, and as it is difficult to form a uniform film with a large area through such methods, they may not be appropriate for a solar cell. In addition, the deposition method may lose a material at a rate ranging from about 20 to about 50%, increasing the price of a solar cell.

Accordingly, research on overcoming the drawbacks and developing an alternative technology for replacing the vacuum deposition method has been variously made.

In U.S. Pat. No. 6,127,202, Kapur et al. disclose a method of dispersing a copper indium gallium oxide in an ink with a water base, applying the solution on a substrate, and then reducing the applied product at a temperature ranging from about 400 to about 500° C. under a H₂/N₂ gas atmosphere and simultaneously injecting H₂Se/N₂ gas therein to selenize the reduced product.

In U.S. Pat. No. 6,268,014, Eberspacher and Pauls disclose a technology for forming a film-type or bulk-type GIGS layer using a very fine precursor powder. However, the high temperature reduction or selenization method is not competitive in terms of price or appropriate for mass production.

The selenization using H₂Se or Se flux has the worst drawback of generating very toxic gas. In addition, the reduction and selenization are performed at a high temperature, which is a great stumbling block to formation of a CIGS thin film on a polymer substrate that cannot withstand such high temperature during fabrication of a solar cell.

Therefore, a method of forming a light-absorption layer on a substrate (for example, a flexible substrate) at a low temperature without any damage thereto needs to be developed.

### SUMMARY OF THE INVENTION

One embodiment of the present invention provides a method of manufacturing a light-absorption layer for a solar cell.

Another embodiment of the present invention provides a method of manufacturing a thin film solar cell using the same.

Still another embodiment of the present invention provides a thin film solar cell fabricated in the method of manufacturing a solar cell.

According to one embodiment of the present invention, provided is a method of manufacturing a light-absorption layer for a solar cell that includes: preparing an ink composition including at least one metal precursor including at least one chalcogen element and a solvent; applying the ink composition as a precursor phase on a substrate using a solution process; and photo-sintering the ink composition as a precursor phase applied on the substrate.

The ink composition may further include a solution stabilizer.

The solution stabilizer may include a diketone, an amino alcohol, a polyamine, an ethanol amine, a diethanol amine, a butylamine, an oleic amine, a triethanol amine, propionic acid, hydrochloric acid, or a combination thereof.

The solvent may include a butyl amine, N-methylpyrrolidone (NMP), N,N-dimethyl formamide (DMF), N,N-dimethyl acetamide (DMAc), tetrahydrofuran (THF), methylene chloride (MC), chloroform, 1,2-dichloroethane, methylethylketone (MEK), acetone, propylene carbonate, gamma-butyrolactone (GBL), 1,4-dioxane, propyl acetate, ethyl acetate, polyethylene glycol (PEG), ethylene glycol (EG), diethylene glycol (DEG), pyridine, pentanol, iso-propanol, or a combination thereof.

The method may further include heat-treating the ink composition as a precursor phase applied on a substrate after applying the ink composition on the substrate using a solution process.

The heat treatment for removing a solvent in the ink composition as a precursor phase applied on a substrate may be performed at a temperature ranging from about 50 to about 200° C.

The photo-sintering may be performed using a white short pulse.

The white short pulse may last for about 0.1 to about 500 ms and pause for about 0.1 to about 500 ms.

The white short pulse may have pulse energy ranging from about 5 to about 200 J/cm².

The white short pulse may have a pulse number ranging from about 1 to about 99.

At least one metal precursor including at least one chalcogen element may be an inorganic salt.

The inorganic salt may include an anion selected from a hydroxide anion, an acetate anion, a propionate anion, an acetylacetonate anion, a 2,2,6,6-tetramethyl-3,5-heptanedionate anion, a methoxide anion, a sec-butoxide anion, a t-butoxide anion, an n-propoxide anion, an i-propoxide anion, an ethoxide anion, a phosphate anion, an alkylphosphate anion, a nitrate anion, a perchlorate anion, a sulfate anion, an alkylsulfonate anion, a phenoxide anion, a bromide anion, an iodide anion, a chloride anion, and a combination thereof.

According to another embodiment of the present invention, provided is a method of manufacturing a thin film solar cell that includes: forming a rear electrode on a substrate; forming a light-absorption layer on the rear electrode; and sequentially forming a buffer layer and a transparent electrode on the light-absorption layer, wherein the light-absorption layer is manufactured in the method of manufacturing a light-absorption layer for a solar cell according to one embodiment.

According to yet another embodiment of the present invention, provided is a thin film solar cell including: a transparent electrode; a light-absorption layer formed on the rear side of the transparent electrode and absorbing solar light and generating electromotive force; a buffer layer formed between the transparent electrode and the light-absorption layer; and a rear electrode formed on the rear side of the light-absorption layer, wherein the light-absorption layer is manufactured according to the method of manufacturing a light-absorption layer for a solar cell according to one embodiment.

The light-absorption layer for a solar cell may be formed at room temperature under an air atmosphere in the method according to one embodiment of the present invention.

In addition, the manufacturing method may be appropriate for a solution process and thus may effectively form an operation layer (e.g., the light-absorption layer) on a flexible substrate through a printing process therein.

Furthermore, the manufacturing method may not include a selenization process and thus may be environmentally-friendly.

Therefore, the manufacturing method may form a semiconductor operation layer (e.g., a light-absorption layer) on a flexible substrate with a large area.

### BRIEF DESCRIPTION OF THE DRAWINGS

FIG. 1 is a schematic view of a thin film solar cell according to one embodiment of the present invention.

FIG. 2 is a SEM photograph of the light-absorption layer after the heat treatment but before the photo-sintering according to Example 1.

FIG. 3 is a SEM photograph of the light-absorption layer according to Comparative Example 1.

FIG. 4 is a SEM photograph of the light-absorption layer after the photo-sintering according to Example 1.

FIG. 5 provides XRD data of the light-absorption layer before the heat treatment but before the photo-sintering according to Example 1, the XRD data of the light-absorption layer according to Comparative Example 1, and the XRD data of the light-absorption layer after the photo-sintering according to Example 1.

FIG. 6 provides light absorption data of the light-absorption layer before the photo-sintering according to Example 1, the light absorption data of the light-absorption layer according to Comparative Example 1, and the light absorption data of the light-absorption layer after the photo-sintering according to Example 1.

FIG. 7 shows SEM photographs of the surface of the light-absorption layer before the photo-sintering (a) and after the photo-sintering (b) according to Example 2.

### DETAILED DESCRIPTION

Exemplary embodiments of the present invention will hereinafter be described in detail. However, these embodiments are only exemplary, and the present invention is not limited thereto.

In one embodiment of the present invention, a method of manufacturing a light-absorption layer for a solar cell includes preparing an ink composition including at least one metal precursor including at least one chalcogen element and a solvent, applying the ink composition as a precursor phase on a substrate using a solution process, and photo-sintering the ink composition as a precursor phase applied on the substrate.

The method of manufacturing a light-absorption layer for a solar cell according to the embodiment of the present invention may provide a light-absorption layer for a solar cell that is formed using an ink composition not having nanoparticles but including a precursor phase.

The precursor phase is an ink phase that is capable of being used for a solution process, for example, a sol, a gel, a sol-gel, and the like. However, the ink composition may have any phase that is capable of being used for a solution process without a particular limit.

However, the precursor phase may be different from a conventional metal particle, and refers to a solution prepared by dissolving a metal precursor in the solvent.

Herein, the method may form a light-absorption layer with a large area using a solution process. In addition, the method may be economical.

In particular, when a conventional nanoparticle ink is used, nanoparticles therein are mainly synthesized by using hydrazine, an explosive toxic material, and thus may cause problems in the process.

In addition, the conventional nanoparticle ink may additionally include a dispersing agent or may need another inconvenient process of changing a ligand on the surface of nanoparticles to secure solution dispersity of the nanoparticles.

Furthermore, a light-absorption layer is hard to form on a flexible polymer substrate, since nanoparticles are sintered at a high temperature of greater than or equal to about 300° C.

However, the present invention may stably form a uniform thin film (e.g., a light-absorption layer) by using the precursor phase instead of toxic and dangerous hydrazine, and thus uses no dispersing agent.

In addition, since a precursor-phased ink composition according to the present invention may be coated and photo-sintered into a thin film (e.g., a light-absorption layer) in a short time, the light-absorption layer may be formed even on a thermally-weak polymer substrate without any damage thereto.

The chalcogen element includes S, Se, Te, and the like belonging to the same group as oxygen in the periodic table.

The ink composition may further include a metal precursor not including a chalcogen element, such as Cu, Cd, Te, Pb, Ga, Zn, In, Sn, and the like, as well as at least one metal precursor including at least one chalcogen element.

The metal precursor not including a chalcogen element as well as a metal precursor including at least one chalcogen element may form a light-absorption layer for a solar cell having an excellent light absorption rate.

The at least one metal precursor including at least one chalcogen element may be an inorganic salt. In addition, the metal precursor not including a chalcogen element may independently be an inorganic salt.

The inorganic salt may include an anion selected from a hydroxide anion, an acetate anion, a propionate anion, an acetylacetonate anion, a 2,2,6,6-tetramethyl-3,5-heptanedionate anion, a methoxide anion, a sec-butoxide anion, a t-butoxide anion, an n-propoxide anion, an i-propoxide anion, an ethoxide anion, a phosphate anion, an alkylphosphate anion, a nitrate anion, a perchlorate anion, a sulfate anion, an alkylsulfonate anion, a phenoxide anion, a bromide anion, an iodide anion, a chloride anion, and a combination thereof.

The substrate may have no particular limit as long as it is used for an electronic device, but may include, for example, glass, ceramic, stainless steel, copper, aluminum, and other metallic substrates, a polymer substrate, and the like. Specifically, the substrate may include a flexible polymer substrate such as a polyamide-based substrate, a polyethylene-based substrate, a polypropylene-based substrate, a polyethylene terephthalate-based substrate, a polyethylene sulfone-based substrate, and the like. In addition, the substrate may be paper. Furthermore, the substrate may be molybdenum.

In the process of applying the ink composition as a precursor phase on a substrate using a solution process, the application process may be various methods such as spraying, screen printing, spin coating, ink-jet printing, coating using a blade (e.g., doctor blade), and the like. However, the application process is not limited thereto.

The ink composition may further include a solution stabilizer.

The solution stabilizer may include a diketone, an amino alcohol, a polyamine, an ethanol amine, a diethanol amine, a butylamine, an oleic amine, a triethanol amine, propionic acid, hydrochloric acid, or a combination thereof, but is not limited thereto.

The solvent may include a butyl amine, N-methylpyrrolidone (NMP), N,N-dimethyl formamide (DMF), N,N-dimethyl acetamide (DMAc), tetrahydrofuran (THF), methylene chloride (MC), chloroform, 1,2-dichloroethane, methylethylketone (MEK), acetone, propylene carbonate, gamma-butyrolactone (GBL), 1,4-dioxane, propyl acetate, ethyl acetate, polyethylene glycol (PEG), ethylene glycol (EG), diethylene glycol (DEG), pyridine, pentanol, iso-propanol, or a combination thereof. However, the solvent is not limited thereto.

The method may further include heat-treating the ink composition as a precursor phase applied on a substrate after applying the ink composition as a precursor phase on a substrate using a solution process.

The heat treatment is performed to remove a solvent in the ink composition. When the solvent is removed, the following photo-sintering may be effectively performed.

The heat treatment for removing a solvent in the ink composition as a precursor phase applied on a substrate may be performed at a temperature ranging from about 50 to about 200° C. The heat treatment within the temperature range may not sinter the ink composition but may effectively remove a solvent therein.

The photo-sintering process of the ink composition as a precursor phase applied on the substrate may be performed using a white short pulse.

The white short pulse may last for about 0.1 to about 500 ms.

The white short pulse may pause for about 0.1 to about 500 ms. Specifically, the white short pulse may last for about 3 to about 500 ms and pause for about 10 to about 500 ms.

In addition, the white short pulse may have pulse energy ranging from about 5 to about 200 J/cm². Specifically, the white short pulse may have pulse energy ranging from about 15 to about 200 J/cm² or about 20 to about 200 J/cm².

In addition, the white short pulse may have a pulse number ranging from about 1 to about 99.

The white short pulse conditions may be adjusted depending on a material for sintering.

The photo-sintering may be performed by using a white short pulse sintering system.

The white short pulse sintering system may include a plurality of xenon flash lamps or a single xenon flash lamp, a triggering/controlling circuit, a capacitor, a reflector, a photo wavelength filter, and the like.

In addition, the white short pulse sintering system may include a vertical distance controller to adjust a distance between a xenon flash lamp and a substrate. Furthermore, the white short pulse sintering system may include a flat substrate delivery device such as a conveyor belt, and thus may make a real-time process possible.

Additionally, the white short pulse sintering system includes assistance heating and cooling plates inside the conveyor belt, and thus may improve efficiency and quality of the sintering process.

On the other hand, a lamp housing for a xenon flash lamp is equipped with a quartz tube, and a channel for supplying cold water to cool the lamp along with a separate cooling system may be equipped therewith.

In addition, a wavelength filter is equipped in the white short pulse sintering system to selectively filter light with a designated wavelength, which may vary depending on kinds of a particle and a substrate and size of the particle.

Furthermore, a beam guide made of quartz may be equipped therewith to precisely control passage of light. This white short pulse sintering system may freely control several pulse conditions, for example, pulse duration, pulse off-time, pulse number, pulse peak intensity, average pulse energy, and the like.

The photo-sintered layer may be analyzed regarding component, shape, electrical conductivity, and the like using a scanning electron microscope (SEM), a focused ion beam (FIB), an energy dispersive spectrometer (EDS), an X-ray diffraction (XRD) analyzer, semiconductor analysis (SA) equipment, and the like.

According to another embodiment of the present invention, a thin film solar cell including a transparent electrode, a light-absorption layer formed on the rear side of the transparent electrode and absorbing solar light and generating an electromotive force, a buffer layer formed between the transparent electrode and the light-absorption layer, and a rear electrode formed on the rear side of the light-absorption layer is provided. The light-absorption layer is formed in the method of manufacturing a light-absorption layer for a solar cell according to the embodiment of the present invention.

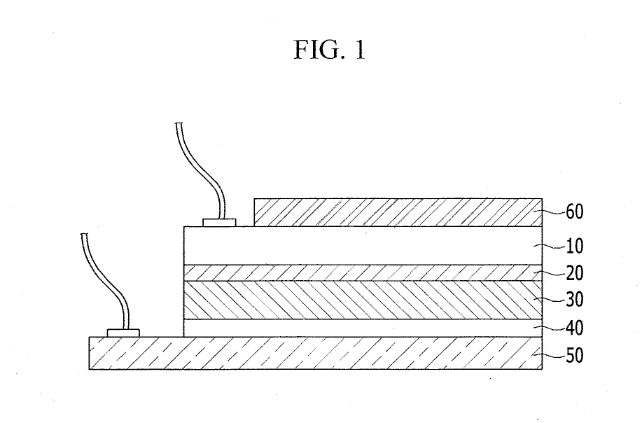

FIG. 1 is a schematic view showing the thin film solar cell.

As shown in FIG. 1, a thin film solar cell may include a transparent electrode 10, a light-absorption layer 30, a buffer layer 20, and a rear electrode 40.

The thin film solar cell may be fabricated by sequentially accumulating the rear electrode 40, the light-absorption layer 30, the buffer layer 20, the transparent electrode 10, and an anti-reflection coating 60 on a substrate 50.

The substrate 50 may be mainly made of glass. The glass substrate may include sodalime glass. The sodalime glass substrate is relatively less expensive than a Corning glass substrate, and Na diffused from the sodalime glass may improve efficiency of a solar cell.

The substrate 50 may be formed of a ceramic, stainless steel, copper, and other metallic substrates, or a polymer, and the like, as well as glass, and may also include a flexible polymer substrate.

The rear electrode 40 may include Mo. The Mo may be sputtered and deposited on the substrate 50. The Mo has high electrical conductivity, and forms a ohmic contact with CIS (or GIGS) used as a light-absorption layer. Also, the Mo has high temperature stability under a Se atmosphere.

The light-absorption layer 30 absorbs solar light and generates electromotive force, and may be formed in the method of manufacturing a light-absorption layer for a solar cell according to one embodiment of the present invention.

The buffer layer 20 may include CdS, and the transparent electrode 10 may include ZnO, ITO, and the like. In addition, an anti-reflection coating 60 may be formed on the transparent electrode 10 to prevent reflection of solar light, and is formed using MgF₂.

In another embodiment of the present invention, a method of manufacturing a thin film solar cell includes forming a rear electrode on a substrate, forming a light-absorption layer on the rear electrode, and sequentially forming a buffer layer and a transparent electrode on the light-absorption layer, wherein the light-absorption layer is manufactured according to the method of manufacturing a light-absorption layer for a solar cell according to one embodiment.

The method of manufacturing a thin film solar cell includes sequential accumulation of the rear electrode 40, the light-absorption layer 30, the buffer layer 20, the transparent electrode 10, and the anti-reflection coating 60 on the substrate 50 as aforementioned.

The light-absorption layer 30 may be formed in the method of manufacturing the light-absorption layer for a solar cell according to one embodiment of the present invention.

Hereinafter, the embodiments are illustrated in more detail with reference to examples. However, the following embodiments are exemplary and are not limiting.

### EXAMPLES

### Fabrication of Light-Absorption Layer for Solar Cell

### Example 1

### Photo-Sintering (ITO Substrate)

Under an air atmosphere, 0.1 mmol of In(OAc)₃, 0.11 mmol of CuI, and 0.5 mmol of thiourea were mixed in a mixture of 0.6 mL of 1-butylamine as a solvent and 40 μL of 1-propionic acid as a solution stabilizer.

When the solution became pale yellow from colorless (to determine that the solutes were sufficiently dissolved, that is, metal precursors were sufficiently ionized), the solution was shaked to be mixed for one minute.

Herein, an ITO substrate was used.

The solution was spin-coated on the substrate. The spin coating was performed at a speed of 1300 rpm for 30 seconds.

After the spin coating, the coated substrate was heat-treated to remove the solvent at 150° C. for 10 minutes.

Then, the resulting product was photo-sintered by using a xenon flash lamp pulse light, forming a light-absorption layer.

The pulse light had pulse energy of about 40 J/cm². The photo-sintering was performed for 20 ms. Herein, five pulses lasted for 5 ms and paused for 10 ms.

### Example 2

### Photo-Sintering (Polyimide Substrate)

A light-absorption layer was formed according to the same method as Example 1, except for using a polyimide substrate instead of the ITO substrate.

### Comparative Example 1

### Thermal Sintering

A light-absorption layer was formed according to the same method as Example 1, except for performing heat treatment at 250° C. for 20 minutes instead of the photo-sintering.

### Experimental Example

SEM (Scanning Electron Microscope) Photograph

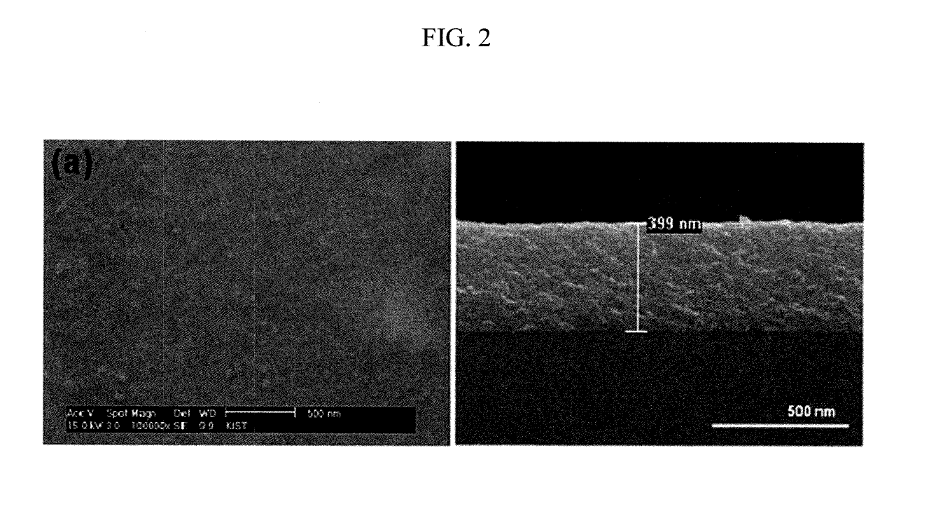

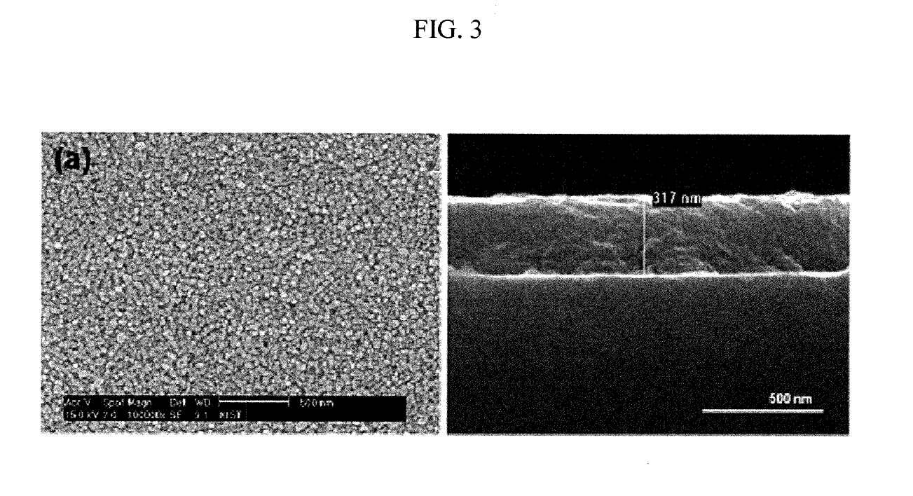

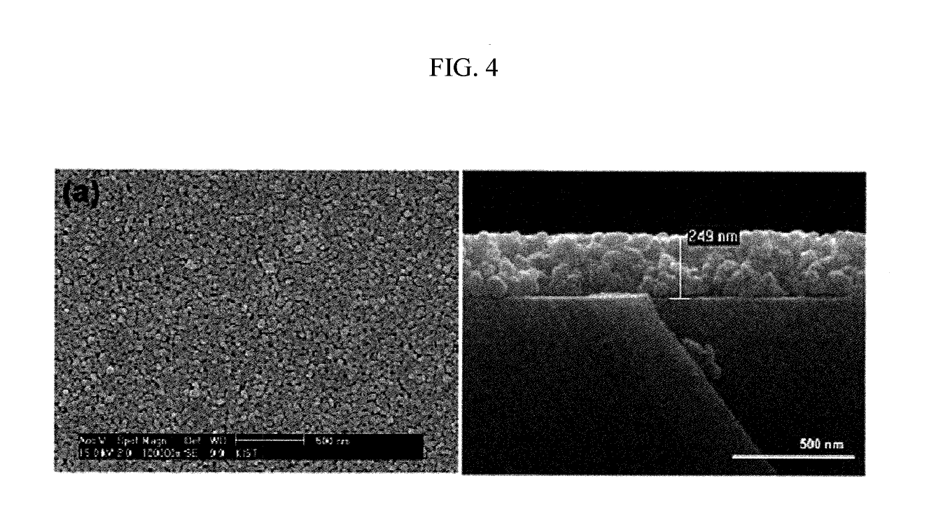

FIG. 2 is a SEM photograph of the light-absorption layer according to Example 1 after the heat treatment but before the photo-sintering, FIG. 3 is a SEM photograph of the light-absorption layer according to Comparative Example 1, and FIG. 4 is a SEM photograph of the light-absorption layer according to Example 1 after the photo-sintering.

In FIGS. 2, 3, and 4, (a) is a SEM photograph of the surface of the light-absorption layer, and (b) is a cross-sectional SEM photograph thereof.

Referring to FIGS. 3 and 4, the photo-sintered light-absorption layer according to Example 1 had a crystal size and shape corresponding to the thin film according to Comparative Example 1.

XRD Analysis

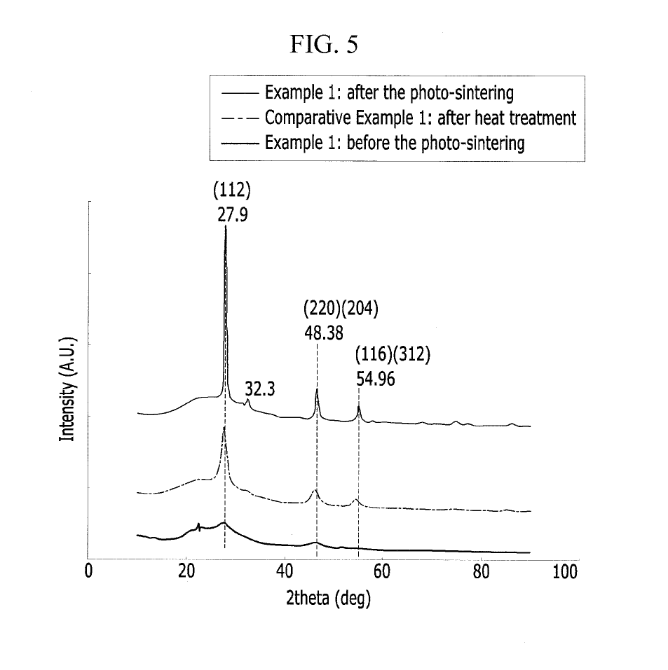

FIG. 5 provides XRD data of the light-absorption layer after the heat treatment according to Example 1, XRD data of the light-absorption layer according to Comparative Example 1, and XRD data of the photo-sintered light-absorption layer according to Example 1.

Referring to the XRD data of the photo-sintered light-absorption layer according to Example 1, the CIS light-absorption layer was identified to have 112, 220/204, and 116/312 chalcogen-based crystal sides and to have better CIS crystallinity than Comparative Example 1.

Light Absorption Characteristics

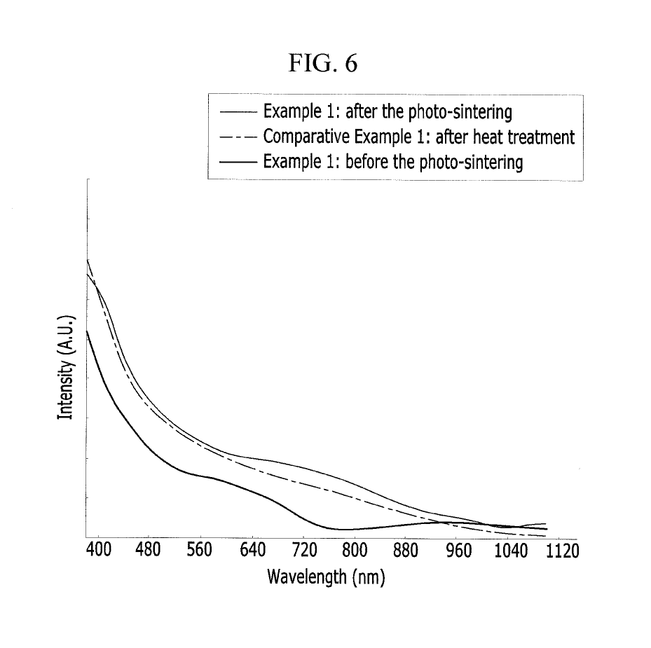

FIG. 6 provides light absorption data of the light-absorption layer after the heat treatment but before the photo-sintering according to Example 1, of the light-absorption layer according to Comparative Example 1, and of the light-absorption layer after the photo-sintering according to Example 1. The light absorption data were measured under the following conditions.

A UV-visible spectroscope (MECASIS, OPTIZEN 3220UV) was used to measure the precursor phase and light absorption of a light-absorption layer before the photo-sintering and after the photo-sintering within a range of 300 to 1100 nm.

The light-absorption layer after the photo-sintering according to Example 1 had a band gap of about 1.29 eV, which corresponded to the photo-absorption characteristic of the light-absorption layer according to Comparative Example 1.

Evaluation of Light-Absorption Layer on Polymer Substrate

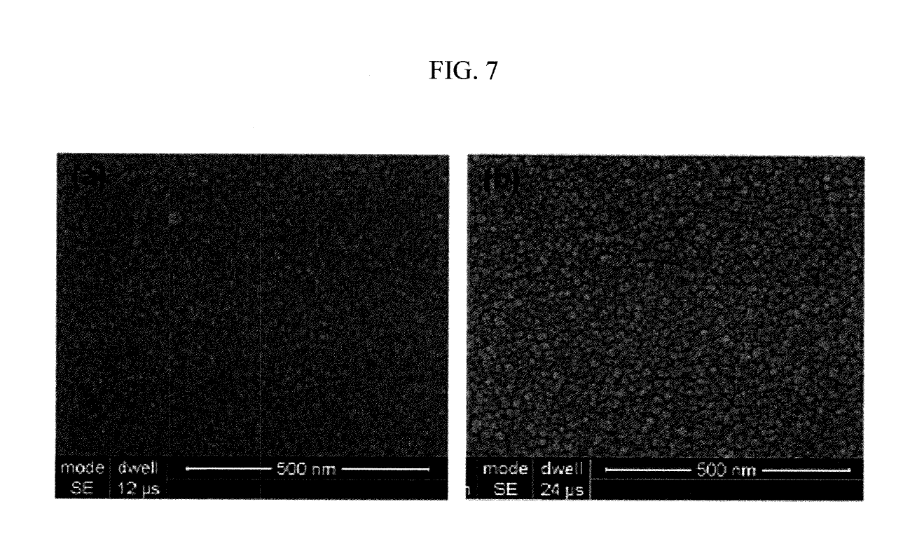

FIG. 7 shows SEM photographs of the surface of the light-absorption layer before the photo-sintering (a) and after the photo-sintering (b) according to Example 2.

As shown in FIG. 7, when a light-absorption layer was sintered on a polyimide substrate, a CIS crystalline light-absorption layer was formed without causing thermal damage to the polymer substrate.

Accordingly, Example 2 shows that a light-absorption layer may be formed on a flexible substrate.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims. Therefore, the aforementioned embodiments should be understood to be exemplary but not limiting the present invention in any way.

### DESCRIPTION OF SYMBOLS

| | |
|---|---|
| 10: transparent electrode | 20: buffer layer |
| 30: light-absorption layer | 40: rear electrode |
| 50: substrate | 60: anti-reflection coating |

What is claimed is:

1. A method of manufacturing a light-absorption layer for a solar cell, comprising:
preparing an ink composition including at least one metal precursor including at least one chalcogen element and a solvent;
applying the ink composition as a precursor phase on a substrate using a solution process; and
photo-sintering the ink composition applied on the substrate as a precursor phase.

2. The method of claim 1, wherein the ink composition further comprises a solution stabilizer.

3. The method of claim 2, wherein the solution stabilizer comprises a diketone, an amino alcohol, a polyamine, an ethanol amine, a diethanol amine, a butylamine, an oleic amine, a triethanol amine, propionic acid, hydrochloric acid, or a combination thereof.

4. The method of claim 1, wherein the solvent comprises a butyl amine, N-methylpyrrolidone (NMP), N,N-dimethyl formamide (DMF), N,N-dimethyl acetamide (DMAc), tetrahydrofuran (THF), methylene chloride (MC), chloroform, 1,2-dichloroethane, methylethylketone (MEK), acetone, propylene carbonate, gamma-butyrolactone (GBL), 1,4-dioxane, propyl acetate, ethyl acetate, polyethylene glycol (PEG), ethylene glycol (EG), diethylene glycol (DEG), pyridine, pentanol, iso-propanol, or a combination thereof.

5. The method of claim 1, wherein the method further comprises heat-treating the ink composition applied as a precursor phase on a substrate after applying the ink composition on the substrate using a solution process.

6. The method of claim 5, wherein the heat treatment for removing a solvent in the ink composition as a precursor phase applied on a substrate is performed at a temperature ranging from about 50 to about 200° C.

7. The method of claim 1, wherein the photo-sintering of the ink composition as a precursor phase applied on the substrate is performed using a white short pulse.

8. The method of claim 7, wherein the white short pulse lasts for about 0.1 to about 500 ms and pauses for about 0.1 to about 500 ms.

9. The method of claim 7, wherein the white short pulse has pulse energy ranging from about 5 to about 200 J/cm².

10. The method of claim 7, wherein the white short pulse has a pulse number ranging from about 1 to about 99.

11. The method of claim 1, wherein the at least one metal precursor including at least one chalcogen element is an inorganic salt.

12. The method of claim 11, wherein the inorganic salt comprises an anion selected from a hydroxide anion, an acetate anion, a propionate anion, an acetylacetonate anion, a 2,2,6,6-tetramethyl-3,5-heptanedionate anion, a methoxide anion, a sec-butoxide anion, a t-butoxide anion, an n-propoxide anion, an i-propoxide anion, an ethoxide anion, a phosphate anion, an alkylphosphate anion, a nitrate anion, a perchlorate anion, a sulfate anion, an alkylsulfonate anion, a phenoxide anion, a bromide anion, an iodide anion, a chloride anion, and a combination thereof.

13. A method of manufacturing a thin film solar cell, comprising
forming a rear electrode on a substrate;
forming a light-absorption layer on the rear electrode; and
sequentially forming a buffer layer and a transparent electrode on the light-absorption layer,
wherein the light-absorption layer is manufactured according to the method of claim 1.

14. A thin film solar cell comprising:
a transparent electrode;
a light-absorption layer formed on the rear side of the transparent electrode and absorbing solar light and generating electric power;
a buffer layer formed between the transparent electrode and the light-absorption layer; and
a rear electrode formed on the rear side of the light-absorption layer,
wherein the light-absorption layer is formed in the method of claims 1.
